(19) United States
(12) Patent Application Publication
(10) Pub. No.: US 2023/0396233 A1
(43) Pub. Date: Dec. 7, 2023

(54) SURFACE ACOUSTIC WAVE DEVICES HAVING REDUCED SIZE

(71) Applicants: SKYWORKS SOLUTIONS, INC., Irvine, CA (US); TOHOKU UNIVERSITY, Sendai-shi (JP)

(72) Inventors: Hiroyuki NAKAMURA, Osaka-Fu (JP); Rei GOTO, Osaka-Shi (JP); Keiichi MAKI, Suita-Shi (JP); Michio KADOTA, Sendai-Shi (JP); Shuji TANAKA, Sendai-Shi (JP)

(21) Appl. No.: 18/203,293

(22) Filed: May 30, 2023

Related U.S. Application Data
(60) Provisional application No. 63/346,959, filed on May 30, 2022.

(51) Int. Cl. H03H 9/145; H03H 9/25; H03H 9/02; H03H 3/10; H03H 9/64

(52) U.S. Cl. CPC H03H 9/14544; H03H 9/25; H03H 9/02559; H03H 9/02834; H03H 3/10; H03H 9/6489

(57) ABSTRACT

In some embodiments, a surface acoustic wave device can include a piezoelectric substrate and an interdigital transducer electrode implemented on a surface of the piezoelectric substrate, such that the surface acoustic device supports a surface acoustic wave having a wavelength λ and a phase velocity less than 3,000 m/s with an electromechanical coupling coefficient of at least 9.0. In some embodiments, the phase velocity less than 2,000 m/s, and the surface acoustic wave can include a lowest asymmetry (A0) mode. In some embodiments, such a surface acoustic wave device can be implemented in products such as a radio-frequency filter, a radio-frequency module and a wireless device.

### CROSS-REFERENCE TO RELATED APPLICATION(S)

This application claims priority to U.S. Provisional Application No. 63/346,959 filed May 30, 2022, entitled SURFACE ACOUSTIC WAVE DEVICES HAVING REDUCED SIZE, the disclosure of which is hereby expressly incorporated by reference herein in its entirety.

### BACKGROUND

### Field

The present disclosure relates to surface acoustic wave devices and related methods.

### Description of the Related Art

A surface acoustic wave (SAW) resonator typically includes an interdigital transducer (IDT) electrode implemented on a surface of a piezoelectric layer. Such an electrode includes two interdigitized sets of fingers, and in such a configuration, the distance between two neighboring fingers of the same set is approximately the same as the wavelength λ of a surface acoustic wave supported by the IDT electrode.

In many applications, the foregoing SAW resonator can be utilized as a radio-frequency (RF) filter based on the wavelength λ. Such a filter can provide a number of desirable features.

### SUMMARY

In accordance with a number of implementations, the present disclosure relates to a surface acoustic wave device that includes a piezoelectric substrate and an interdigital transducer electrode implemented on a surface of the piezoelectric substrate, such that the surface acoustic device supports a surface acoustic wave having a wavelength λ and a phase velocity less than 3,000 m/s with an electromechanical coupling coefficient of at least 9.0.

In some embodiments, the phase velocity can be less than 2,000 m/s.

In some embodiments, the surface acoustic wave can include a lowest asymmetry (A0) mode.

In some embodiments, the piezoelectric substrate can include LiNbO₃ crystal having Euler angles (φ, δ, ψ). In some embodiments, the angle θ can be in a range 30 degrees<θ<50 degrees. In some embodiments, the angle θ can be in a range 35 degrees<θ<45 degrees. In some embodiments, the LiNbO₃ piezoelectric substrate can have a thickness in a range of 0.15λ to 0.40λ, in a range of 0.16λ to 0.35λ, in a range of 0.17λ to 0.30λ, or in a range of 0.18λ to 0.25λ.

In some embodiments, the interdigital transducer electrode can be formed from aluminum, molybdenum, copper, tungsten or platinum. The interdigital transducer electrode can have a thickness in a range of 0.02λ to 0.10λ.

In some embodiments, the surface acoustic wave device can further include a layer implemented over or under the piezoelectric substrate. The layer can be configured to provide improved temperature coefficient of frequency (TCF) property of the SAW device. In some embodiments, the layer can be formed from silicon dioxide (SiO₂). In some embodiments, the SiO₂ layer can be implemented under the piezoelectric substrate. In some embodiments, the SiO₂ layer can have a thickness in a range of 0.03λ to 0.1λ.

In some embodiments, the surface acoustic wave device can further include a support substrate implemented below the piezoelectric substrate. In some embodiments, the support substrate can be formed from silicon, quartz, sapphire, glass, silica, germanium, or alumina. In some embodiments, the support substrate can be directly under the piezoelectric substrate.

In some embodiments, the layer for providing improved TCF property can be between the support substrate and the piezoelectric substrate. In some embodiments, the support substrate can define a cavity that exposes a portion of the layer.

In some implementations, the present disclosure relates to a radio-frequency filter that includes an input node for receiving a signal and an output node for providing a filtered signal. The radio-frequency filter further includes a surface acoustic wave device implemented to be electrically between the input node and the output node. The surface acoustic wave device includes a piezoelectric substrate and an interdigital transducer electrode implemented on a surface of the piezoelectric substrate, such that the surface acoustic device supports a surface acoustic wave having wavelength λ and a phase velocity less than 3,000 m/s with an electromechanical coupling coefficient of at least 9.0.

In some embodiments, the phase velocity can be less than 2,000 m/s. In some embodiments, the surface acoustic wave can include a lowest asymmetry (A0) mode. In some embodiments, the piezoelectric substrate can include LiNbO₃ crystal. In some embodiments, the interdigital transducer electrode can be formed from aluminum, molybdenum, copper, tungsten or platinum.

In some embodiments, the radio-frequency filter can further include a layer implemented over or under the piezoelectric substrate, and configured to provide improved temperature coefficient of frequency (TCF) property of the SAW device. In some embodiments, the layer can be formed from silicon dioxide (SiO₂). In some embodiments, the SiO₂ layer can be implemented under the piezoelectric substrate.

In some embodiments, the radio-frequency filter can further include a support substrate implemented below the piezoelectric substrate. In some embodiments, the support substrate can be formed from silicon, quartz, sapphire, glass, silica, germanium, or alumina. In some embodiments, the support substrate can be directly under the piezoelectric substrate.

In some embodiments, the layer for providing improved TCF property can be between the support substrate and the piezoelectric substrate. In some embodiments, the support substrate can define a cavity that exposes a portion of the layer.

In some teachings, the present disclosure relates to a radio-frequency module that includes a packaging substrate configured to receive a plurality of components, and a radio-frequency circuit implemented on the packaging substrate and configured to support either or both of transmission and reception of signals. The radio-frequency module further includes a radio-frequency filter configured to provide filtering for at least some of the signals. The radio-frequency filter includes a piezoelectric substrate and an interdigital transducer electrode implemented on a surface of the piezoelectric substrate, such that the surface acoustic device supports a surface acoustic wave having wavelength λ and a phase velocity less than 3,000 m/s with an electromechanical coupling coefficient of at least 9.0.

According to some implementations, the present disclosure relates to a wireless device that includes a transceiver, an antenna, and a wireless system implemented to be electrically between the transceiver and the antenna. The wireless system includes a filter configured to provide filtering functionality for the wireless system. The filter includes a piezoelectric substrate and an interdigital transducer electrode implemented on a surface of the piezoelectric substrate, such that the surface acoustic device supports a surface acoustic wave having wavelength λ and a phase velocity less than 3,000 m/s with an electromechanical coupling coefficient of at least 9.0.

In some teachings, the present disclosure relates to a method for fabricating a surface acoustic wave device. The method includes forming or providing a piezoelectric substrate, and implementing an interdigital transducer electrode on a surface of the piezoelectric substrate, such that the surface acoustic device supports a surface acoustic wave having a wavelength λ and a phase velocity less than 3,000 m/s with an electromechanical coupling coefficient of at least 9.0.

In some embodiments, the phase velocity can be less than 2,000 m/s. In some embodiments, the surface acoustic wave can include a lowest asymmetry (A0) mode.

In some embodiments, the piezoelectric substrate can include LiNbO₃ crystal having Euler angles (θ, θ, ψ). In some embodiments, the angle θ can be in a range 30 degrees<θ<50 degrees. In some embodiments, the angle θ can be in a range 35 degrees<θ<45 degrees. In some embodiments, the LiNbO₃ piezoelectric substrate can have a thickness in a range of 0.15λ to 0.40λ, in a range of 0.16λ to in a range of 0.17λ to 0.30λ, or in a range of 0.18λ to 0.25λ.

In some embodiments, the interdigital transducer electrode can be formed from aluminum, molybdenum, copper, tungsten or platinum. In some embodiments, the interdigital transducer electrode can have a thickness in a range of 0.02λ to 0.10λ.

In some embodiments, the method can further include implementing a layer over or under the piezoelectric substrate to provide improved temperature coefficient of frequency (TCF) property of the SAW device. In some embodiments, the layer can be formed from silicon dioxide (SiO₂). In some embodiments, the SiO₂ layer can be implemented under the piezoelectric substrate. In some embodiments, the SiO₂ layer can have a thickness in a range of 0.03λ to 0.1λ.

In some embodiments, the method can further include implementing a support substrate below the piezoelectric substrate. In some embodiments, the support substrate can be formed from silicon, quartz, sapphire, glass, silica, germanium, or alumina. In some embodiments, the support substrate can be directly under the piezoelectric substrate.

In some embodiments, the layer for providing improved TCF property can be between the support substrate and the piezoelectric substrate. In some embodiments, the support substrate can define a cavity that exposes a portion of the layer.

In some embodiments, the surface acoustic device can be part of a radio-frequency filter.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a plan view of a surface acoustic wave (SAW) device having a piezoelectric substrate and an interdigital transducer (IDT) electrode implemented thereon.

FIG. 1B shows a side sectional view of the SAW device of FIG. 1A.

FIG. 2 shows an example SAW device configured to operate in a lowest asymmetry mode (A0 mode) of wave having a wavelength λ, with a piezoelectric substrate formed from LiNbO₃ (LN) having a thickness, and an IDT electrode formed from aluminum (Al) having a thickness.

FIG. 3 shows phase velocity curves for various modes as a function of thickness of an LN piezoelectric substrate.

FIG. 4 shows that in some embodiments, a SAW device configured to support an A0 mode as described herein can include a preferred range of piezoelectric substrate cut angle θ of Euler angles (φ, θ, ψ).

FIG. 5 shows that in some embodiments, a SAW device configured to support an A0 mode as described herein can include a preferred range of piezoelectric substrate thickness.

FIG. 6 shows that in some embodiments, a SAW device can include an undercoat layer provided under a piezoelectric substrate to improve temperature coefficient of frequency (TCF) property of the SAW device.

FIG. 7 shows that in some embodiments, a SAW device can include an overcoat layer provided over an IDT electrode and a piezoelectric substrate to improve temperature coefficient of frequency (TCF) property of the SAW device.

FIG. 8 shows k², phase velocity and TCF plots resulting from simulation for the SAW device of FIG. 6, as the silicon dioxide (SiO₂) layer thickness is swept from 0 to 0.2λ.

FIG. 9 shows k², phase velocity and TCF plots resulting from simulation for the SAW device of FIG. 7, as the silicon dioxide (SiO₂) layer thickness is swept from 0.1λ to 0.2λ.

FIG. 10 shows phase velocity and k² plots as a function of IDT electrode thickness resulting from simulation for SAW devices with different IDT electrode materials.

FIG. 11 shows a SAW device that includes a piezoelectric substrate and an IDT electrode implemented thereon to provide one or more properties as described herein.

FIG. 12 shows a SAW device that includes a piezoelectric substrate, an IDT electrode implemented thereon, and an overcoat layer covering the IDT electrode to provide one or more properties as described herein.

FIG. 13 shows a SAW device that includes a piezoelectric substrate, an IDT electrode implemented thereon, and an undercoat layer provided in contact with a surface of the piezoelectric substrate opposite to the surface on which the IDT electrode is implemented to provide one or more properties as described herein.

FIG. 14 shows a SAW device that is similar to the SAW device of FIG. 13, but where a support substrate is shown to define a cavity that exposes a respective portion of the underside of the undercoat layer.

FIG. 15 shows that in some embodiments, multiple units of SAW resonators can be fabricated while in an array form.

FIG. 16 shows that in some embodiments, a SAW resonator having one or more features as described herein can be implemented as a part of a packaged device.

FIG. 17 shows that in some embodiments, the SAW resonator based packaged device of FIG. 16 can be a packaged filter device.

FIG. 18 shows that in some embodiments, a radio-frequency (RF) module can include an assembly of one or more RF filters.

FIG. 19 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

In many radio-frequency (RF) applications, size of a filter die size contributes significantly to the size of a corresponding RF module. One size reduction technique involves use of a low velocity propagation mode to reduce the size of a surface acoustic wave (SAW) resonator.

Disclosed herein are examples related to SAW resonators having low velocity properties. In some embodiments, a low velocity can include a phase velocity of a propagation mode, where the phase velocity is less than 3,000 m/s, less than 2,500 m/s, or less than 2,100 m/s. In some embodiments, a SAW resonator as described herein can be configured to support an A0 (lowest asymmetry) mode with a thin LiNbO3 (LN) layer to generate a very low velocity propagating mode. For example, a phase velocity of about 2,000 m/s can be achieved, which is significantly slower than previous solutions.

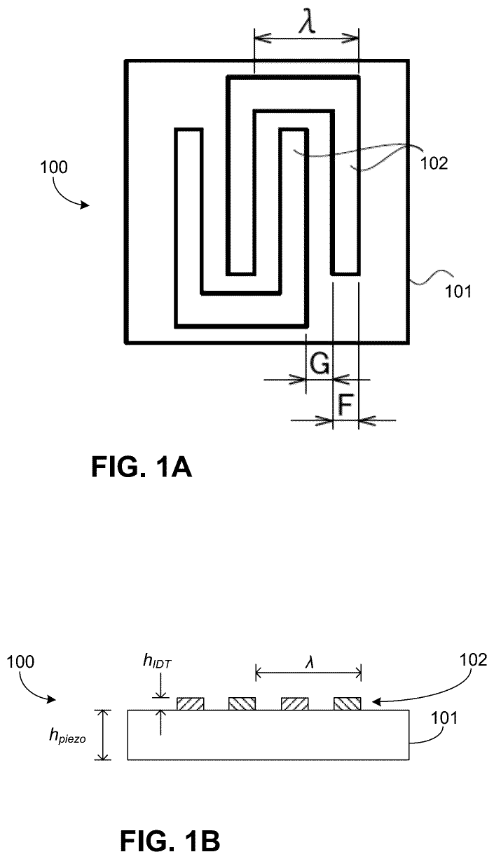

FIG. 1A shows a plan view of a surface acoustic wave (SAW) device 100 having a piezoelectric substrate 101 and an interdigital transducer (IDT) electrode 102 implemented thereon. FIG. 1B shows a side sectional view of the SAW device 100 of FIG. 1A. In some embodiments, and as shown in FIG. 1B, the IDT electrode 102 can be formed on the piezoelectric substrate 101.

Referring to FIGS. 1A and 1B, the distance between two neighboring fingers of the IDT electrode 102 is approximately the same as the wavelength λ of a surface acoustic wave associated with the IDT electrode 102. Further, each finger of the IDT electrode 102 is shown to have a lateral width of F, and a gap distance of G is shown to be provided between two interdigitized neighboring fingers.

Referring to FIG. 1B, the piezoelectric substrate 101 is shown to have a thickness of h_{piezo}, and the IDT electrode 102 is shown to have a thickness of him-.

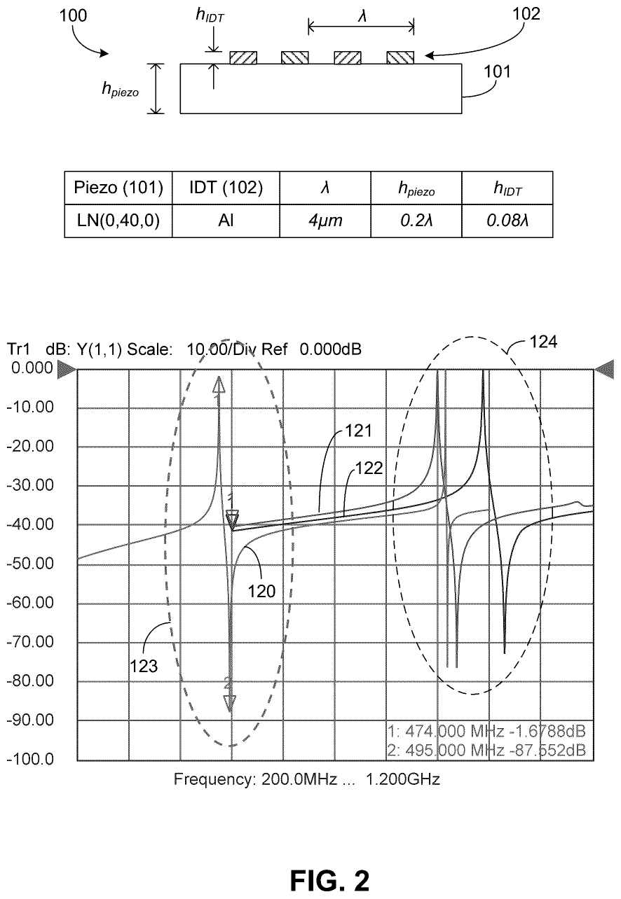

FIG. 2 shows an example SAW device 100 configured to operate in a lowest asymmetry mode (A0 mode) of wave having a wavelength λ=4 μm, with a piezoelectric substrate 101 formed from LiNbO₃ (LN) having Euler angles (0, 40, 0) and a thickness h_{piezo}=0.2λ, and an IDT electrode 102 formed from aluminum (Al) having a thickness h_{IDT}=0.08λ. The IDT electrode of FIG. 2 has a finger count NIDT representative of 75λ, and finger width of 80 μm.

Configured in the foregoing manner, and by way of simulations including an example admittance modulus plot, FIG. 2 further shows an admittance response 120 for the SAW device 100 including an A0 mode in a region 123 and an A1 (first order asymmetry) mode in a region 124.

As examples of size comparisons, the example admittance plot of FIG. 2 also shows an admittance response 121 for a temperature compensated (TC) SAW device with LN having Euler angles (0, 38, 0) and SiO₂ with a thickness of 0.3λ, and an admittance response 122 for a non-TC SAW device with LN having Euler angles (0, 132, 0) and an aluminum (Al) IDT electrode having a thickness of 0.08λ. Each of the admittance responses 121, 122 is shown to have an A1 mode in the region generally indicated as 124.

In the example simulations of FIG. 2, it is noted that the A1 mode of the TCSAW device (with the response 121) provides a phase velocity V of 3,588 m/s and an IDT electrode capacitance C of 2.81 pF, thereby providing a ratio V/C that can be a size indicator. Compared to the V/C ratio for the foregoing TCSAW device, the non-TC SAW device (with the response 122) provides a phase velocity V of 4,108 m/s and an IDT electrode capacitance C of 2.48 pF, thereby providing a ratio V/C that is 1.3 times the V/C ratio of the TCSAW device. For the SAW device 100 (having the response 120), the A0 mode provides a phase velocity V of 1,896 m/s and an IDT electrode capacitance C of 2.80 pF, thereby providing a ratio V/C that is 0.53 times the V/C ratio of the TCSAW device. Thus, one can see that the example reduction in size of 53% (compared to the TCSAW device) is significant.

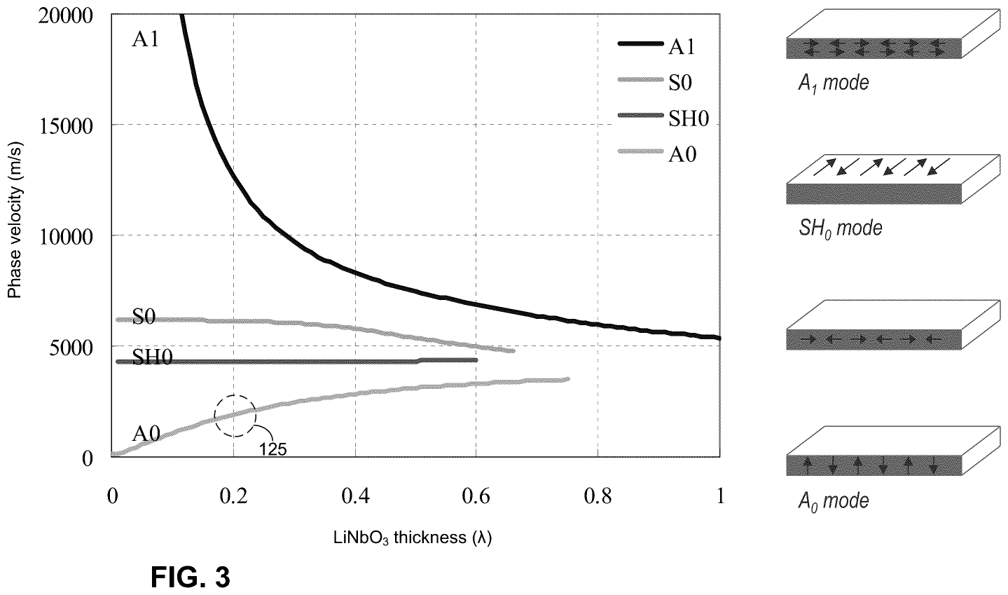

FIG. 3 shows phase velocity curves for various modes as a function of thickness of an LN piezoelectric substrate having Euler angles (0, 0, 0). More particularly, simulated plots are shown for an A1 (first order asymmetry) mode, an S0 (lowest symmetry) mode, an SH0 (lowest shear horizontal) mode, and an A0 (lowest asymmetry) mode. One can see that the A0 mode generally provides lower phase velocity than the other modes (SH0, S0, A1) when the LN piezoelectric substrate is less than 0.7λ or 0.6λ. Within such a range of LN piezoelectric substrate thickness, the phase velocity for the A0 mode is shown to increase monotonically with the LN thickness. Thus, a thinner LN piezoelectric substrate, such as a thickness of 0.2λ indicated as 125, can provide a desirable low phase velocity value. Accordingly, in some embodiments, a SAW device having one or more features as described herein can have a thin piezoelectric substrate such as a thin LN piezoelectric substrate having a thickness that is less than 0.4λ, less than 0.35λ, less than 0.3λ, or less than 0.25λ.

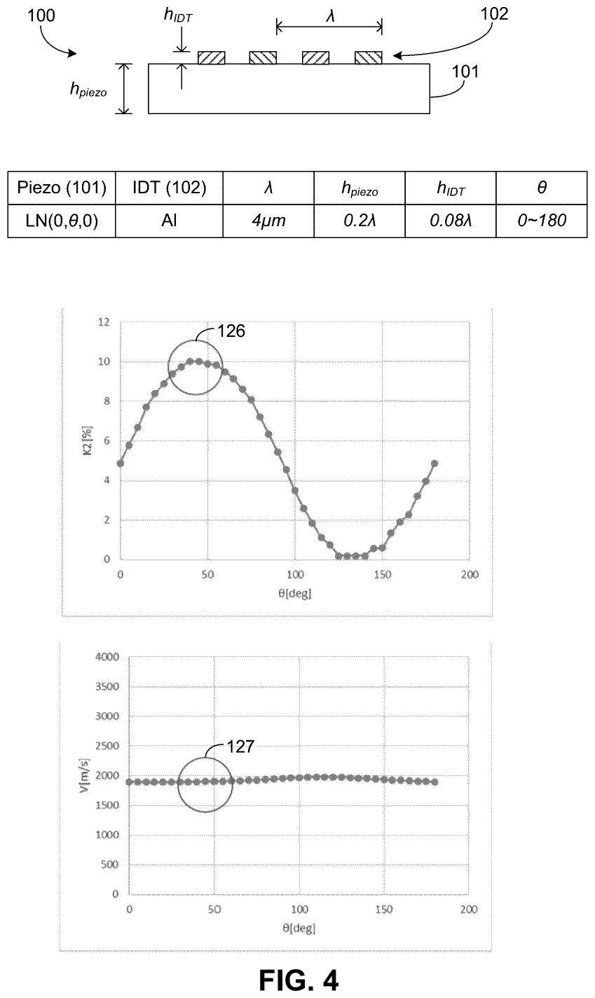

FIG. 4 shows that in some embodiments, a SAW device configured to support an A0 mode as described herein can include a preferred range of piezoelectric substrate cut angle θ of Euler angles (φ, θ, ψ). More particularly, FIG. 4 shows a plot of electromechanical coupling coefficient k² as the cut angle θ is swept through a range of 0 degree to 180 degrees, for a SAW device 100 that is similar to the example of FIG. 2 other than the varying nature of the cut angle θ.

One can see that k² has better values when the cut angle θ has a value in a range 20 degrees<θ<70 degrees, and a peak value of approximately 10% when the cut angle θ has a value of approximately 40 degrees. Thus, in some embodiments, a SAW device having one or more features as described herein can have a piezoelectric substrate such as an LN piezoelectric substrate having a cut angle θ in a range 20 degrees<θ<70 degrees, in a range 20 degrees<θ<60 degrees, in a range degrees<θ<55 degrees, in a range 30 degrees<θ<50 degrees, or in a range 35 degrees<θ<45 degrees. In FIG. 4, such preferred ranges of cut angle θ is generally indicated as 126.

In the example of FIG. 4, one can see in the lower panel that the phase velocity remains less than or near 2,000 m/s throughout the range of cut angle θ between 0 degree to 180 degrees, including the preferred cut angle θ range indicated as 127.

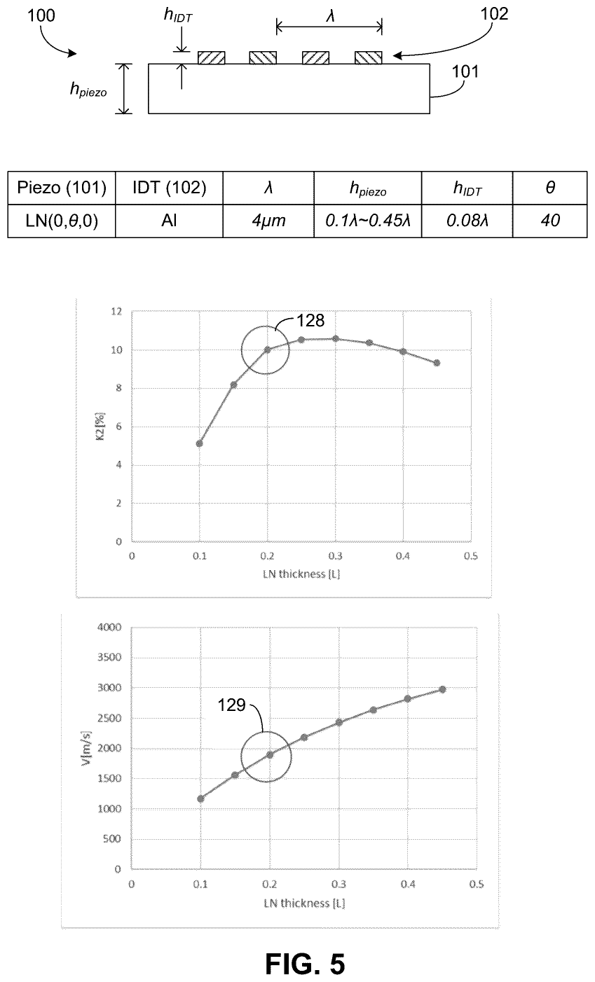

FIG. 5 shows that in some embodiments, a SAW device configured to support an A0 mode as described herein can include a preferred range of piezoelectric substrate thickness. More particularly, FIG. 5 shows a plot of electromechanical coupling coefficient k² as an LN piezoelectric substrate thickness is swept through a range of 0.1λ to 0.45λ, for a SAW device 100 that is similar to the example of FIG. 2 other than the varying nature of the LN thickness.

One can see that k² has better values when the LN thickness has a value in a range 0.15λ to 0.45λ. However, and as shown in the lower panel of FIG. 5, if a phase velocity value less than 3,000 m/s (when LN thickness is about 0.45λ) is desired, an LN thickness range of 0.15λ to 0.40λ is preferable when lower phase velocity and higher k² are desired. Thus, in some embodiments, a SAW device having one or more features as described herein can have a piezoelectric substrate such as an LN piezoelectric substrate having a thickness in a range of 0.15λ to 0.40λ, in a range of 0.16λ to 0.35λ, in a range of 0.17λ to 0.30λ, or in a range of 0.18λ to 0.25λ.

Referring to FIG. 5, it is noted that a selected LN thickness of 0.2λ (indicated as 128 in the upper panel) does not provide a maximum value of k². However, such a selected LN thickness of 0.2λ (indicated as 129 in the lower panel) does provide a phase velocity that is less than 2,000 m/s and a TCF (temperature coefficient of frequency) of −55/−66 ppm/deg. Accordingly, the LN thickness of 0.2λ can be an example of a desired set of parameters where k² has a value greater than or equal to 10 and phase velocity is less than or equal to 2,000 m/s.

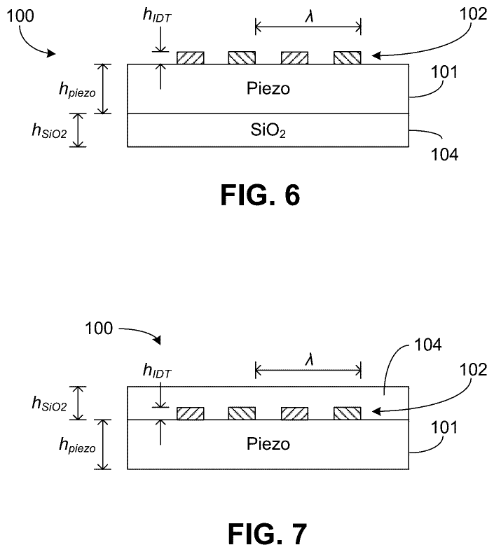

FIG. 6 shows that in some embodiments, a SAW device 100 can include an undercoat layer 104 provided under a piezoelectric substrate 101 to improve temperature coefficient of frequency (TCF) property of the SAW device. In the example of FIG. 6, an IDT electrode 102 is shown to be formed on the piezoelectric substrate 101, similar to the SAW device 100 of FIG. 1B. In some embodiments the undercoat layer 104 can be formed from material such as silicon dioxide (SiO₂) having a thickness h_{SiO2}.

FIG. 7 shows that in some embodiments, a SAW device 100 can include an overcoat layer 104 provided over an IDT electrode 102 and a piezoelectric substrate 101 to improve temperature coefficient of frequency (TCF) property of the SAW device. In the example of FIG. 7, the IDT electrode 102 is shown to be formed on the piezoelectric substrate 101, similar to the SAW device 100 of FIG. 1B. In some embodiments, the overcoat layer 104 can completely cover the IDT electrode 102. In some embodiments the overcoat layer 104 can be formed from material such as silicon dioxide (SiO₂) having a thickness h_{SiO2}.

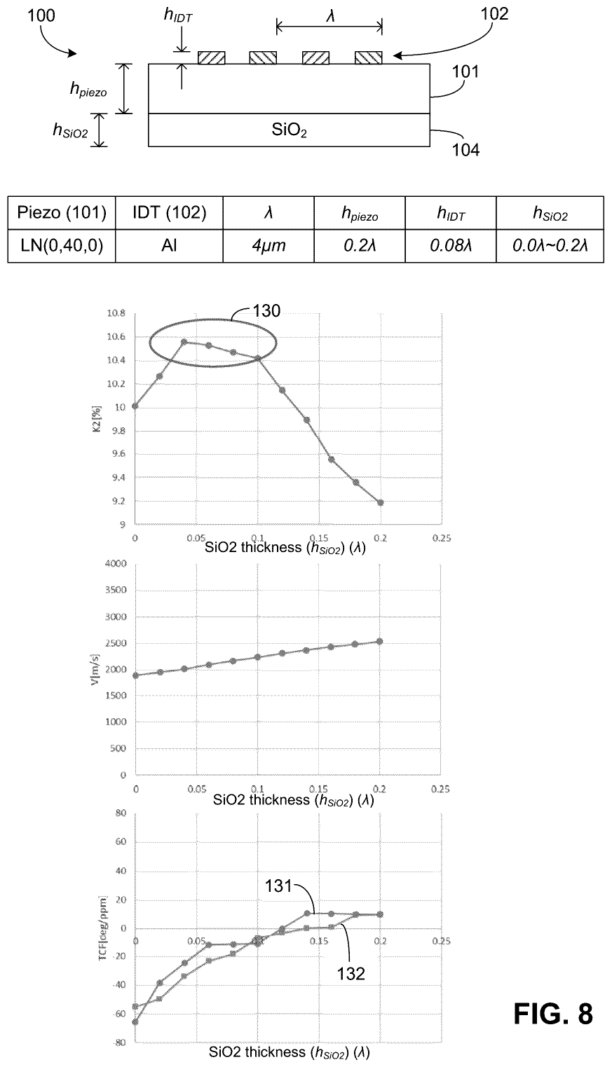

FIG. 8 shows k², phase velocity and TCF plots resulting from simulation for the SAW device 100 of FIG. 6, as the silicon dioxide (SiO₂) layer (104) thickness h_{SiO2} is swept from 0 to 0.2λ. In the example of FIG. 8, the LN piezoelectric substrate 101 and the IDT electrode 102 are configured similar to the SAW device 100 of FIG. 2, with LN Euler angles (0, 40, 0), LN thickness h_{piezo}=0.2λ, and Al IDT electrode thickness h_{IDT}=0.08λ.

Referring to the k² plot of FIG. 8, one can see that for a range of SiO₂ thickness h_{SiO2} (e.g., about 0.03λ to 0.1λ and generally indicated as 130), k² performance improves (e.g., k²≥10.4) when compared to the k² value of approximately for the h_{piezo}=0.2λ configuration of FIG. 5 without an SiO₂ layer (as well as the configuration of FIG. 8 where h_{SiO2}=0).

Referring to the phase velocity plot of FIG. 8, one can see that phase velocity increases monotonically as SiO₂ thickness h_{SiO2} increases. As with the example of FIG. 5 (without an SiO₂ layer) where h_{piezo}=0.2λ, phase velocity in FIG. 8 is less than 2,000 m/s when h_{SiO2}=0. Phase velocity then increases to about 2,500 m/s when h_{SiO2}=0.2λ.

Referring to the bottom panel of FIG. 8, the two curves indicated as 132, 131 corresponds to TCF of resonant frequency and TCF of anti-resonant frequency, respectively, as the thickness of an SiO₂ layer is swept from 0 to 0.2λ. One can see that the presence of the SiO₂ layer 104 generally improves TCF performance.

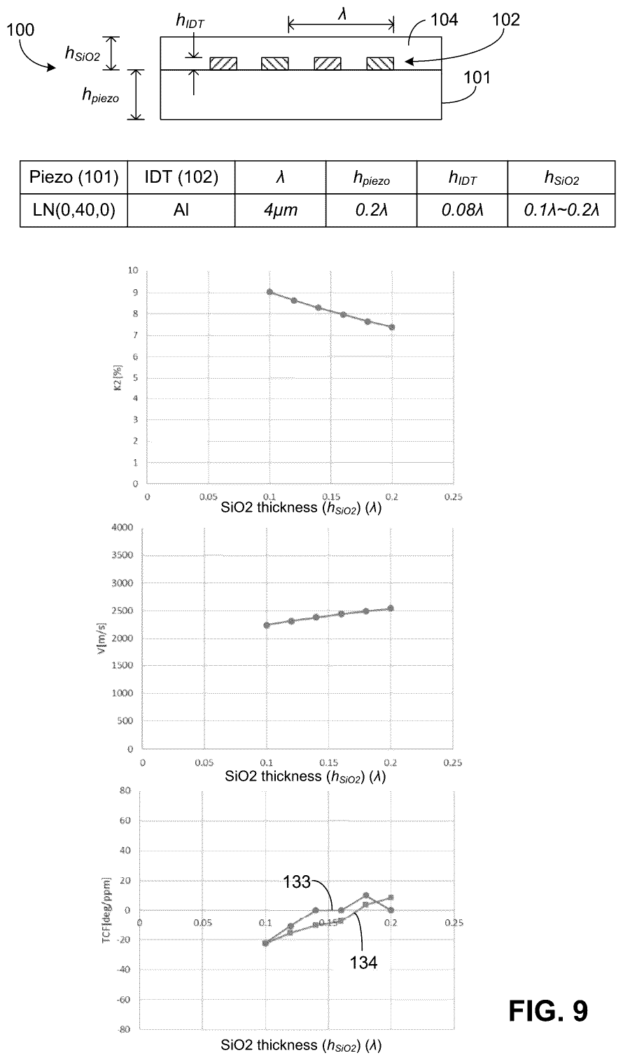

FIG. 9 shows k², phase velocity and TCF plots resulting from simulation for the SAW device 100 of FIG. 7, as the silicon dioxide (SiO₂) layer (104) thickness h_{SiO2} is swept from 0.1λ to 0.2λ. In the example of FIG. 9, the LN piezoelectric substrate 101 and the IDT electrode 102 are configured similar to the SAW device 100 of FIG. 2, with LN Euler angles (0, 40, 0), LN thickness h_{piezo}=0.2λ, and Al IDT electrode thickness h_{IDT}=0.08λ.

Referring to the k² plot of FIG. 9, one can see that for the entire range of SiO₂ thickness h_{SiO2} (0.1λ to 0.2λ), k² performance is degraded (e.g., k²≤9) when compared to the k² value of approximately 10 for the h_{piezo}=0.2λ configuration of FIG. 5 without an SiO₂ layer.

Referring to the phase velocity plot of FIG. 9, one can see that phase velocity increases monotonically as SiO₂ thickness h_{SiO2} increases. For example, phase velocity is about 2,500 m/s when h_{SiO2}=0.1λ, and about 2,500 m/s when h_{SiO2}=0.2λ.

Referring to the bottom panel of FIG. 9, the two curves indicated as 134, 133 corresponds to TCF of resonant frequency and TCF of anti-resonant frequency, respectively, as the thickness of an SiO₂ layer is swept from 0.1λ. to 0.2λ. One can see that the presence of the SiO₂ layer 104 generally improves TCF performance.

Referring to the examples of FIGS. 8 and 9, one can see that in some embodiments, the configuration of FIG. 8 (with an SiO₂ undercoat layer 104) is preferable over the configuration of FIG. 9 (with an SiO₂ overcoat layer 104) if improved k² performance is desired.

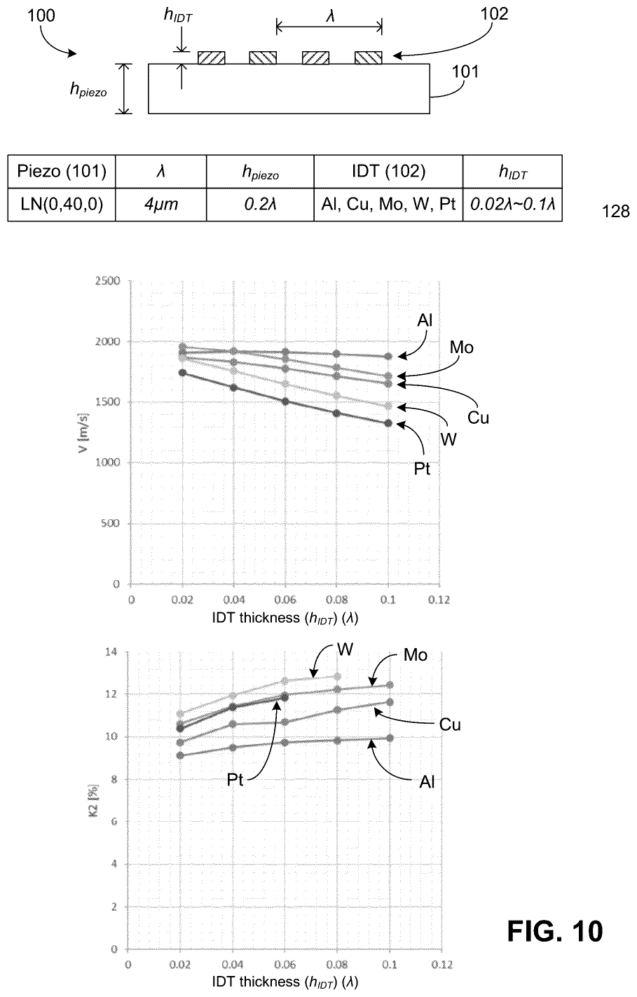

FIG. 10 shows phase velocity and k² plots as a function of IDT electrode thickness resulting from simulation for SAW devices with different IDT electrode materials. In the example of FIG. 10, a SAW device 100 is shown to have an LN piezoelectric substrate 101 that is similar to the SAW device 100 of FIG. 2, with LN Euler angles (0, 40, 0) and LN thickness h_{piezo}=0.2λ. Such a SAW device is provided with an IDT electrode 102 formed from aluminum (Al) having a density of 2.70 g/cm³, copper (Cu) having a density of 8.96 g/cm³, molybdenum (Mo) having a density of 10.28 g/cm³, tungsten (W) having a density of 19.25 g/cm³, or platinum (Pt) having a density of 21.45 g/cm³.

As shown in the phase velocity plots of FIG. 10, one can see that phase velocity generally decreases (for Cu, Mo, W, Pt), or remains generally similar (for Al) as the IDT electrode thickness h_{IDT} increases from 0.02λ to 0.10λ. In all of the example materials and thickness values, phase velocity values are less than 2,000 m/s.

As shown in the k² plots of FIG. 10, one can see that k² generally increases as the IDT electrode thickness h_{IDT} increases from 0.02λ to 0.10λ. In all of the example materials and thickness values, phase velocity values are less than 2,000 m/s.

Referring to the k² and phase velocity plots of FIG. 10, one can see that higher density IDT electrodes generally provides lower phase velocity values and higher k² values lower density IDT electrodes. For example, higher density IDT electrodes such as W and Pt electrodes provide lower phase velocity values than lower density IDT electrodes such as Al and Mo electrodes. Further, higher density IDT electrodes such as W and Pt electrodes provide lower phase velocity values than a lower density IDT electrode such as Al electrode. Taken together one can see that in some embodiments, an IDT electrode having higher density may be desirable for a SAW device to provide low phase velocity and high k² properties.

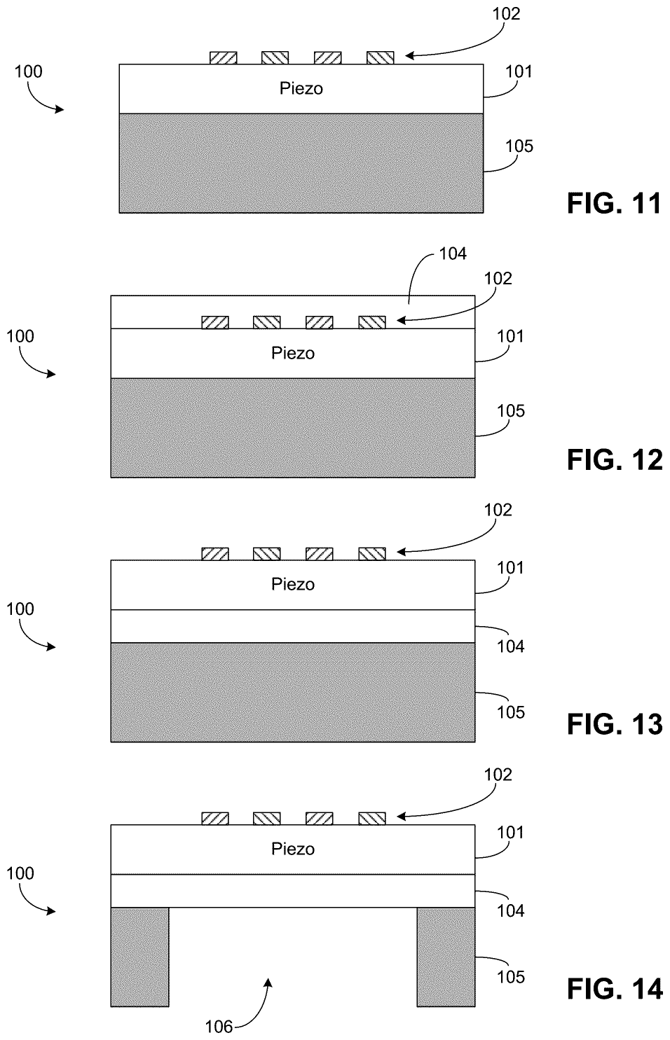

FIGS. 11 to 14 show that in some embodiments, a SAW device having one or more features as described herein can include a support substrate. For example, FIG. 11 shows a SAW device 100 that includes a piezoelectric substrate 101 and an IDT electrode 102 implemented thereon to provide one or more properties as described herein, such as one or more properties associated with the SAW device 100 of FIG. 2. In FIG. 11, the SAW device 100 is shown to further include a support substrate 105 provided in contact with a surface of the piezoelectric substrate 101 opposite to the surface on which the IDT electrode 102 is provided.

In another example, FIG. 12 shows a SAW device 100 that includes a piezoelectric substrate 101, an IDT electrode 102 implemented thereon, and an overcoat layer 104 covering the IDT electrode 102 to provide one or more properties as described herein, such as one or more properties associated with the SAW device 100 of FIG. 7. In FIG. 12, the SAW device 100 is shown to further include a support substrate 105 provided in contact with a surface of the piezoelectric substrate 101 opposite to the surface on which the IDT electrode 102 is provided.

In yet another example, FIG. 13 shows a SAW device 100 that includes a piezoelectric substrate 101, an IDT electrode 102 implemented thereon, and an undercoat layer 104 provided in contact with a surface of the piezoelectric substrate 101 opposite to the surface on which the IDT electrode 102 is implemented to provide one or more properties as described herein, such as one or more properties associated with the SAW device 100 of FIG. 5. In FIG. 13, the SAW device 100 is shown to further include a support substrate 105 provided in contact with a surface of the undercoat layer 104 such that the undercoat layer 104 is between the piezoelectric substrate 101 and the support substrate 105.

In yet another example, FIG. 14 shows a SAW device 100 that is similar to the SAW device 100 of FIG. 13. In the example of FIG. 14, the support substrate 105 is shown to define a cavity 106 that exposes a respective portion of the underside of the undercoat layer 104. In some embodiments, such a cavity can be dimensioned and positioned to be generally underneath the IDT electrode 102.

In some embodiments, the support substrates 105 in the examples of FIGS. 11 to 14 can be formed from semiconductor or insulator, such as silicon, quartz, sapphire, glass, silica, germanium, or alumina. In some embodiments, such support substrates can be configured to provide support for the respective piezoelectric substrates, especially if a piezoelectric substrate is relatively thin.

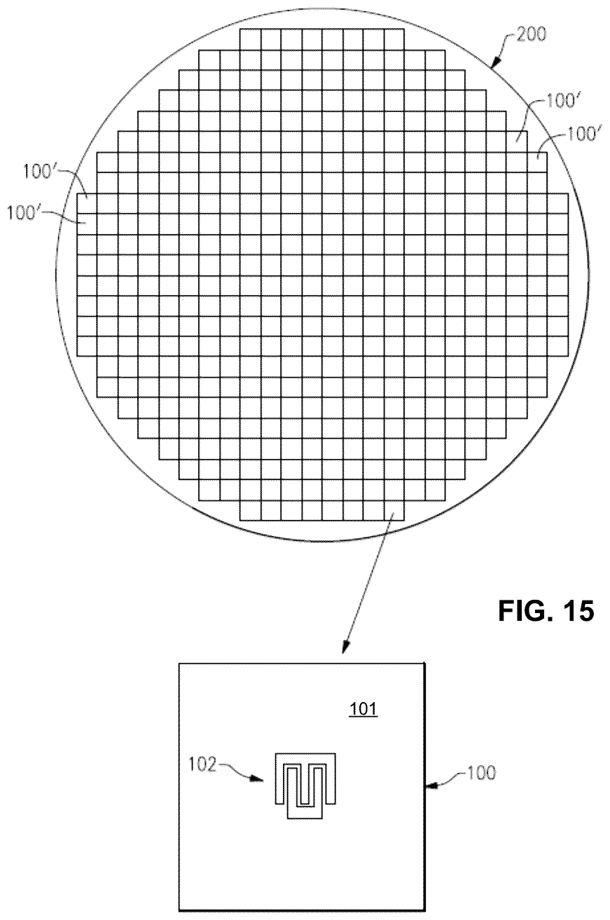

In some embodiments, a SAW resonator having one or more features as described herein can be implemented as a product, and such a product can be included in another product. Examples of such different products are described in reference to FIGS. 15-19.

FIG. 15 shows that in some embodiments, multiple units of SAW resonators can be fabricated while in an array form. For example, a wafer 200 can include an array of units 100′, and such units can be processed through a number of process steps while joined together.

Upon completion of process steps in the foregoing wafer format, the array of units 100′ can be singulated to provide multiple SAW resonators 100. FIG. 15 depicts one of such SAW resonators 100, and such a SAW resonator can include one or more features as described herein.

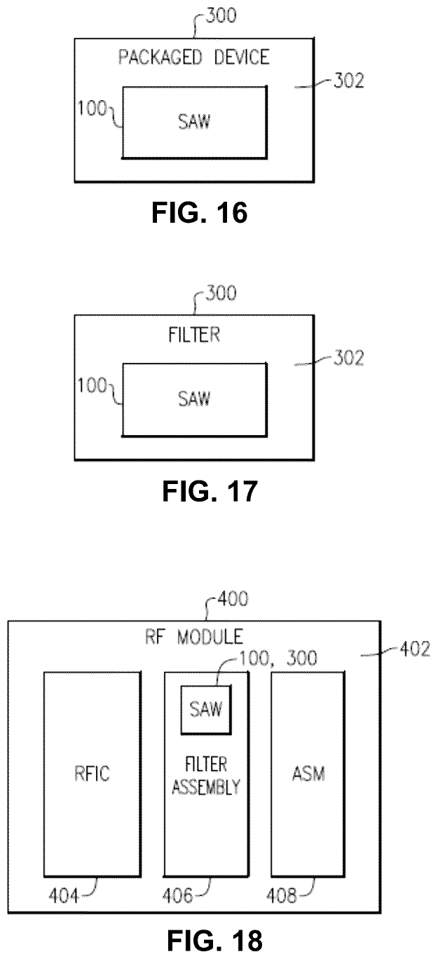

FIG. 16 shows that in some embodiments, a SAW resonator 100 having one or more features as described herein can be implemented as a part of a packaged device 300. Such a packaged device can include a packaging substrate 302 configured to receive and support one or more components, including the SAW resonator 100.

FIG. 17 shows that in some embodiments, the SAW resonator based packaged device 300 of FIG. 16 can be a packaged filter device 300. Such a filter device can include a packaging substrate 302 suitable for receiving and supporting a SAW resonator 100 configured to provide a filtering functionality such as RF filtering functionality.

FIG. 18 shows that in some embodiments, a radio-frequency (RF) module 400 can include an assembly 406 of one or more RF filters. Such filter(s) can be SAW resonator based filter(s) 100, packaged filter(s) 300, or some combination thereof. In some embodiments, the RF module 400 of FIG. 18 can also include, for example, an RF integrated circuit (RFIC) 404, and an antenna switch module (ASM) 408. Such a module can be, for example, a front-end module configured to support wireless operations. In some embodiments, some of all of the foregoing components can be mounted on and supported by a packaging substrate 402.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

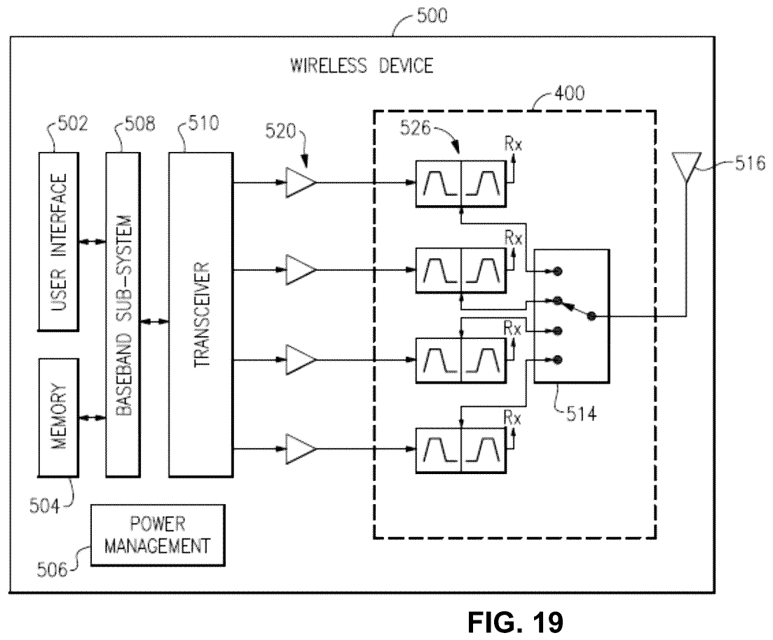

FIG. 19 depicts an example wireless device 500 having one or more advantageous features described herein. In the context of a module having one or more features as described herein, such a module can be generally depicted by a dashed box 400, and can be implemented as, for example, a front-end module (FEM). In such an example, one or more SAW filters as described herein can be included in, for example, an assembly of filters such as duplexers 526.

Referring to FIG. 19, power amplifiers (PAs) 520 can receive their respective RF signals from a transceiver 510 that can be configured and operated in known manners to generate RF signals to be amplified and transmitted, and to process received signals. The transceiver 510 is shown to interact with a baseband sub-system 408 that is configured to provide conversion between data and/or voice signals suitable for a user and RF signals suitable for the transceiver 510. The transceiver 510 can also be in communication with a power management component 506 that is configured to manage power for the operation of the wireless device 500. Such power management can also control operations of the baseband sub-system 508 and the module 400.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, outputs of the PAs 520 are shown to be routed to their respective duplexers 526. Such amplified and filtered signals can be routed to an antenna 516 through an antenna switch 514 for transmission. In some embodiments, the duplexers 526 can allow transmit and receive operations to be performed simultaneously using a common antenna (e.g., 516). In FIG. 19, received signals are shown to be routed to “Rx” paths (not shown) that can include, for example, a low-noise amplifier (LNA).

Although various examples are described herein in the context of a piezoelectric substrate including LiNbO3 (LN), it will be understood that one or more features of the present disclosure can also be implemented utilizing other piezoelectric substrates such as LiTaO₃ (LT).

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A surface acoustic wave device comprising:
a piezoelectric substrate; and
an interdigital transducer electrode implemented on a surface of the piezoelectric substrate, such that the surface acoustic device supports a surface acoustic wave having a wavelength λ and a phase velocity less than 3,000 m/s with an electromechanical coupling coefficient of at least 9.0.

2. The surface acoustic wave device of claim 1 wherein the phase velocity is less than 2,000 m/s.

3. The surface acoustic wave device of claim 1 wherein the surface acoustic wave includes a lowest asymmetry (A0) mode.

4. The surface acoustic wave device of claim 1 wherein the piezoelectric substrate includes LiNbO₃ crystal having Euler angles (φ, θ, ψ).

5. The surface acoustic wave device of claim 4 wherein the angle θ is in a range 30 degrees<θ<50 degrees.

6. The surface acoustic wave device of claim 5 wherein the angle θ is in a range 35 degrees<θ<45 degrees.

7. The surface acoustic wave device of claim 4 wherein the LiNbO₃ piezoelectric substrate has a thickness in a range of 0.15λ to 0.40λ, in a range of 0.16λ to 0.35λ, in a range of 0.17λ to 0.30λ, or in a range of 0.18λ to 0.25λ.

8. The surface acoustic wave device of claim 1 wherein the interdigital transducer electrode is formed from aluminum, molybdenum, copper, tungsten or platinum.

9. The surface acoustic wave device of claim 8 wherein the interdigital transducer electrode has a thickness in a range of 0.02λ to 0.10λ.

10. The surface acoustic wave device of claim 1 further comprising a layer implemented over or under the piezoelectric substrate, the layer configured to provide improved temperature coefficient of frequency (TCF) property of the SAW device.

11. The surface acoustic wave device of claim 10 wherein the layer is formed from silicon dioxide (SiO₂).

12. The surface acoustic wave device of claim 11 wherein the SiO₂ layer is implemented under the piezoelectric substrate.

13. The surface acoustic wave device of claim 11 wherein the SiO₂ layer has a thickness in a range of 0.03λ to 0.1λ.

14. The surface acoustic wave device of claim 1 further comprising a support substrate implemented below the piezoelectric substrate.

15. The surface acoustic wave device of claim 14 wherein the support substrate is formed from silicon, quartz, sapphire, glass, silica, germanium, or alumina.

16. The surface acoustic wave device of claim 14 wherein the support substrate is directly under the piezoelectric substrate.

17. The surface acoustic wave device of claim 14 wherein the layer for providing improved TCF property is between the support substrate and the piezoelectric substrate.

18. The surface acoustic wave device of claim 17 wherein the support substrate defines a cavity that exposes a portion of the layer.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. A wireless device comprising:
a transceiver;
an antenna; and
a wireless system implemented to be electrically between the transceiver and the antenna, the wireless system including a filter configured to provide filtering functionality for the wireless system, the filter including a piezoelectric substrate and an interdigital transducer electrode implemented on a surface of the piezoelectric substrate, such that the surface acoustic device supports a surface acoustic wave having wavelength λ and a phase velocity less than 3,000 m/s with an electromechanical coupling coefficient of at least 9.0.

34. A method for fabricating a surface acoustic wave device, the method comprising:
forming or providing a piezoelectric substrate; and
implementing an interdigital transducer electrode on a surface of the piezoelectric substrate, such that the surface acoustic device supports a surface acoustic wave having a wavelength λ and a phase velocity less than 3,000 m/s with an electromechanical coupling coefficient of at least 9.0.

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)
